(19) United States
(12) Patent Application Publication
(10) Pub. No.: US 2024/0260430 A1
(43) Pub. Date: Aug. 1, 2024

(54) DISPLAY DEVICE

(71) Applicant: LG Display Co., Ltd., Seoul (KR)

(72) Inventors: KwangYong CHOI, Paju-si (KR); EunJi PARK, Gangwon-do (KR); ByeongUk GANG, Seoul (KR)

(73) Assignee: LG Display Co., Ltd., Seoul (KR)

(21) Appl. No.: 18/540,372

(22) Filed: Dec. 14, 2023

(30) Foreign Application Priority Data
Jan. 26, 2023 (KR) 10-2023-0010406

(51) Int. Cl. H10K 59/80; H10K 59/122

(52) U.S. Cl. CPC H10K 59/8792; H10K 59/122; H10K 59/351

(57) ABSTRACT

A display device capable of enhancing the negative bias temperature illumination stress (NBTiS) characteristics and the reliability of a thin film transistor, can include a substrate including having an emission area and a non-emission area, a thin film transistor disposed on the substrate, a passivation layer covering an upper portion of the thin film transistor, an overcoat layer disposed on the passivation layer and having a slit or through hole recessed toward the passivation layer, and a black bank layer disposed on the overcoat layer and formed to have a shape corresponding to the slit or through hole to form a protrusion positioned in the slit or through hole.

### CROSS-REFERENCE TO RELATED APPLICATION

This application claims priority to Korean Patent Application No. 10-2023-0010406, filed in the Republic of Korea on Jan. 26, 2023, which is hereby expressly incorporated by reference in its entirety into the present application.

### BACKGROUND

### Field

Embodiments of the disclosure relate to a display device having enhanced negative bias temperature illumination stress (NBTiS) characteristics.

### Discussion of Related Art

In recent years, the display sector for visually representing electrical information signals has developed rapidly in the information era, and various display devices with excellent performance, such as more compact, lightweight, and low power consumption displays, have been developed accordingly.

Specific examples of such display devices include liquid crystal display devices (LCDs), plasma display panel devices (PDPs), field emission display devices (FEDs), organic light emitting display devices (OLEDs) and the like.

In particular, organic light emitting display devices are self-luminous displays, which have the advantages of fast response, high luminous efficiency, brightness, and large viewing angle as compared to other display devices. Organic light emitting elements applied to the organic light emitting display devices are a new generation of light sources with self-luminance characteristics, which have superior advantages over liquid crystals in terms of viewing angle, contrast, response speed, and power consumption. Further, since the organic light emitting element has a surface light emitting structure, it is easy to implement a flexible form.

However, the organic light emitting display devices have an issue in that the negative bias temperature illumination stress (NBTiS) characteristic of its thin film transistor can be sensitively affected by ambient light.

### BRIEF SUMMARY OF THE DISCLOSURE

The inventors of the disclosure have invented a display device capable of addressing the NBTiS issue by absorbing the light incident on the opening by enhancing the structure of the black bank layer.

Embodiments of the disclosure can provide a display device capable of enhancing the NBTiS characteristics and the reliability of the thin film transistor by minimizing the amount of light introduced to the thin film transistor by absorbing the light incident on the opening through the black bank layer.

Embodiments of the disclosure can provide a display device comprising a substrate including an emission area and a non-emission area, a thin film transistor disposed on the substrate, a passivation layer covering an upper portion of the thin film transistor, an overcoat layer disposed on the passivation layer and having a slit or through hole recessed toward the passivation layer, and a black bank layer disposed on the overcoat layer and formed to have a shape corresponding to the slit or through hole to form a protrusion positioned in the slit or through hole.

According to embodiments of the disclosure, there can be provided a display device capable of enhancing the NBTiS characteristics and the reliability of the thin film transistor by minimizing the amount of light introduced to the thin film transistor by absorbing the light incident on the opening through the black bank layer.

According to embodiments of the disclosure, there can be provided a display device capable of low power consumption by enhancing the aperture ratio by omitting the color filter through an enhanced black bank layer structure.

### BRIEF DESCRIPTION OF THE DRAWINGS

The above and other objects, features, and advantages of the disclosure will be more clearly understood from the following detailed description, taken in conjunction with the accompanying drawings, in which:

FIG. 1 is a block diagram schematically illustrating a configuration of a display device according to an embodiment of the disclosure;

FIG. 2 is a circuit diagram illustrating a circuit configuration of a subpixel of a display device according to an embodiment of the disclosure;

FIG. 3 is a circuit diagram illustrating a circuit configuration of a subpixel of a display device according to an embodiment of the disclosure;

FIG. 4 is a plan view illustrating a display device according to an embodiment of the disclosure;

FIG. 5 is a plan view illustrating a portion of a subpixel of a display device according to an embodiment of the disclosure;

FIG. 6 is a cross-sectional view taken along line A-A′ of FIG. 5;

FIG. 7 is a view illustrating comparison in external light path between a black bank layer with no protrusion and a black bank layer with a protrusion;

FIG. 8 is a cross-sectional view illustrating a portion of a subpixel of a display device according to another embodiment of the disclosure;

FIG. 9 is a cross-sectional view illustrating a portion of a subpixel of a display device according to another embodiment of the disclosure;

FIGS. 10A, 10B, and 10C are cross-sectional views illustrating embodiments having a color filter;

FIGS. 11A and 11B are cross-sectional views illustrating embodiments with no color filter; and

FIGS. 12, 13, 14, 15, and 16 are plan views illustrating a structure in which a slit/hole positioned in a pixel area is disposed according to an embodiment of the disclosure.

### DETAILED DESCRIPTION OF THE EMBODIMENTS

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description can make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” can be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but one or more third elements can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “may” fully encompasses all the meanings of the term “can”.

Hereinafter, various embodiments of the disclosure are described in detail with reference to the accompanying drawings. All the components of each display device according to all embodiments of the present disclosure are operatively coupled and configured.

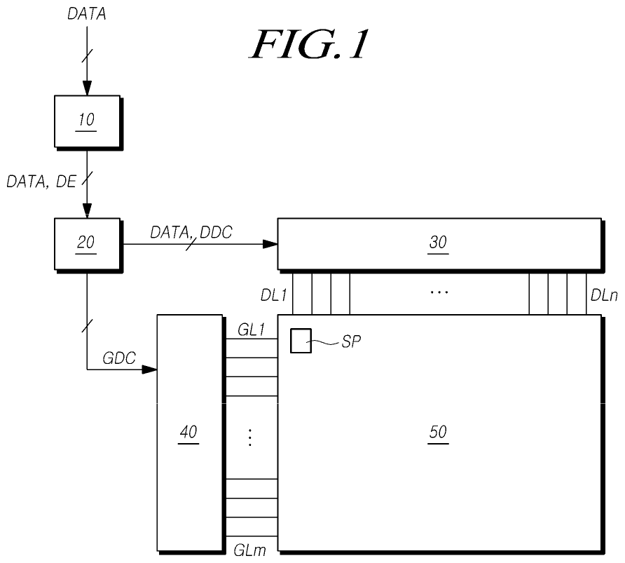

FIG. 1 is a block diagram schematically illustrating a configuration of a display device according to an embodiment of the disclosure.

In the following embodiments, for convenience of description, an organic light emitting display device as the display device is described. However, the display device is not limited thereto, and can include a liquid crystal display device (LCD), a field emission display device (FED), an electroluminescence display device (ELD), or an organic light emitting display device (OLED).

The organic light emitting display device can include an organic film layer formed of an organic material between the first electrode ANO, which is an anode, and the second electrode CAT, which is a cathode. Accordingly, the holes supplied from the first electrode ANO and the electrons supplied from the second electrode CAT can be combined in the organic film layer to form excitons, which are hole-electron pairs, and emit light by energy generated when the excitons return to the bottom state.

Referring to FIG. 1, a display device can include an image processor 10, a timing controller 20, a data driver 30, a gate driver 40, and a display panel 50.

The image processor 10 can output a data enable signal DE and the like together with a data signal DATA supplied from the outside. In addition to the data enable signal DE, the image processor 10 can output one or more of a vertical synchronization signal, a horizontal synchronization signal, and a clock signal. Here, the image processor 10 can be formed in the form of an integrated circuit (IC) on a system circuit board.

The timing controller 20 can receive the data signal DATA together with the driving signal including the data enable signal DE, the vertical synchronization signal, the horizontal synchronization signal, the clock signal, or the like, from the image processor 10.

The timing controller 20 can output a gate timing control signal GDC for controlling the operation timing of the gate driver 40 and a data timing control signal DDC for controlling the operation timing of the data driver 30 based on the driving signal. Here, the timing controller 20 can be formed in the form of an IC on the control circuit board.

The data driver 30 can sample and latch the data signal DATA supplied from the timing controller 20 in response to the data timing control signal DDC supplied from the timing controller 20, convert the data signal DATA into a gamma reference voltage, and output the gamma reference voltage. The data driver 30 can output the data signal DATA through the data lines DL1 to DLn where n can be a positive number such as a positive integer. Here, the data driver 30 can be attached to the substrate in the form of an IC.

The gate driver 40 can output the gate signal while shifting the level of the gate voltage in response to the gate timing control signal GDC supplied from the timing controller 20. The gate driver 40 can output a gate signal through the gate lines GL1 to GLm where m can be a positive number such as a positive integer. Here, the gate driver 40 can be formed in the form of an IC on the gate circuit board or in the form of a gate in panel (GIP) on the display panel 50.

The display panel 50 can display an image corresponding to the data signal DATA and the gate signal supplied from the data driver 30 and the gate driver 40. Here, the display panel 50 can include a plurality of subpixels SP that display an image.

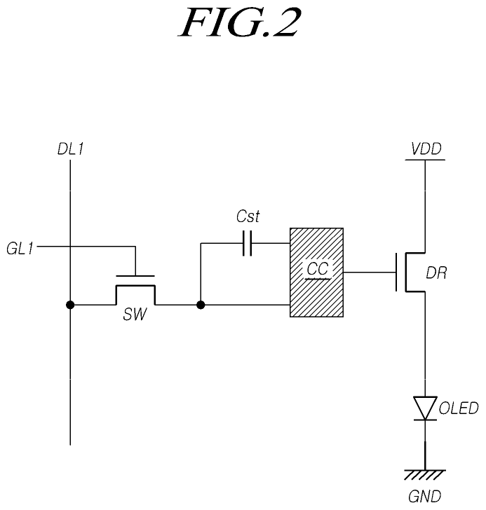

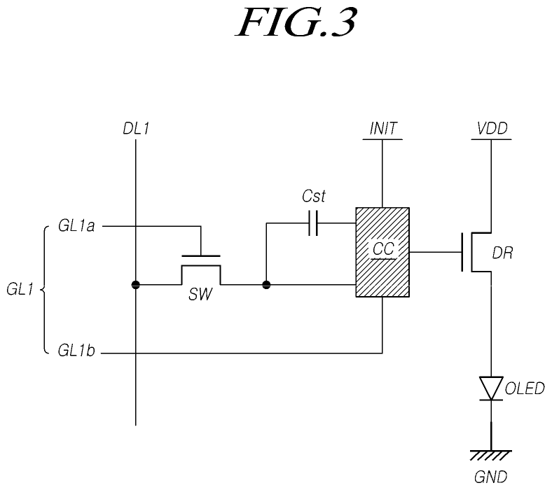

FIG. 2 is a circuit diagram illustrating a circuit configuration of a subpixel according to an embodiment of the disclosure, and FIG. 3 is a circuit diagram illustrating a circuit configuration of a subpixel according to another embodiment of the disclosure. The configurations of FIGS. 2 and 3 can be used in each sub-pixel of the display device in FIG. 1 or in any other display device of the present disclosure.

Referring to FIG. 2, one subpixel SP can include a switching thin film transistor SW, a driving thin film transistor DR, a compensation circuit CC, and an organic light emitting diode OLED. The organic light emitting diode OLED can operate to emit light according to a driving current formed by the driving thin film transistor DR.

The switching thin film transistor SW can perform a switching operation such that the data signal supplied through the first data line DL1 is stored as the data voltage in the capacitor Cst in response to the gate signal supplied through the gate line GL1.

The driving thin film transistor DR can operate such that a driving current flows between the high potential power line VDD and the low potential power line GND according to the data voltage stored in the capacitor Cst.

The compensation circuit CC is a circuit for compensating for the threshold voltage of the driving thin film transistor DR. Further, the capacitor connected to the switching thin film transistor SW or the driving thin film transistor DR can be positioned inside the compensation circuit CC. Here, the compensation circuit CC can include one or more thin film transistors and capacitors. The configuration of the compensation circuit CC varies depending on the compensation method, and detailed examples and descriptions thereof will be omitted.

As illustrated in FIG. 3, when the compensation circuit CC is included, the subpixel SP can further include a signal line and a power line for driving the compensation thin film transistor and supplying a specific signal or power.

The gate line can include a 1-1th gate line GL1a for supplying a gate signal to the switching thin film transistor SW, and a 1-2th gate line GL1b for driving the compensation thin film transistor included in the subpixel SP. The added power line can be defined as an initialization power line INIT for initializing a specific node of the subpixel SP to a specific voltage. However, this is only an example, but the disclosure is not limited thereto.

Meanwhile, in FIGS. 2 and 3, the compensation circuit CC is included in one subpixel SP. However, when the subject of compensation is positioned outside the subpixel SP such as the data driver 30, the compensation circuit CC can be omitted. In other words, one subpixel SP is basically configured as a 2T (Transistor) 1C (Capacitor) structure including a switching thin film transistor SW, a driving thin film transistor DR, a capacitor, and an organic light emitting diode OLED, but can be variously configured as 3T1C, 4T2C, 5T2C, 6T2C, 7T2C, or the like when a compensation circuit CC is added. Further, although FIGS. 2 and 3 illustrate that the compensation circuit CC is positioned between the switching thin film transistor SW and the driving thin film transistor DR, the compensation circuit CC can be further positioned between the driving thin film transistor DR and the organic light emitting diode OLED.

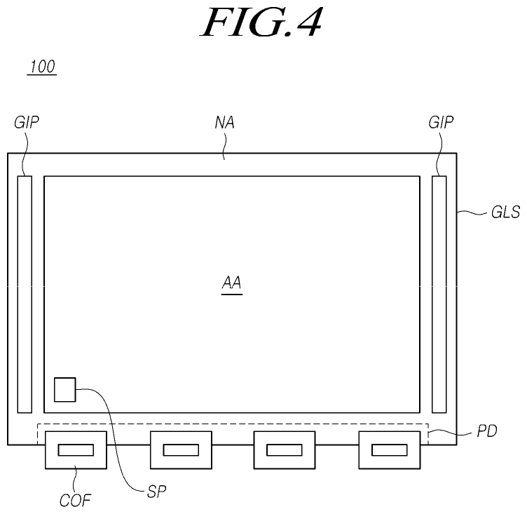

FIG. 4 is a plan view illustrating a display device according to an embodiment of the disclosure.

Referring to FIG. 4, a display device 100 can include a substrate GLS, a display unit (or active area unit) AA, GIP driving units GIP disposed on two opposite sides of the display unit AA, and a pad unit PD disposed under the substrate GLS.

The display unit AA can have a plurality of subpixels SP and implement a full color by emitting red light R, green light G, blue light B, or red light R, green light G, blue light B, and white light W. The GIP driving units GIP can be disposed on two opposite sides of the display unit AA to apply a gate driving signal to the display unit AA. The pad unit PD can be disposed on one side, e.g., a lower side of the display unit AA, and chip-on films COF can be attached to the pad unit PD. The data signal and power applied through the chip-on film COF can be transferred to a plurality of signal lines connected to the display unit AA.

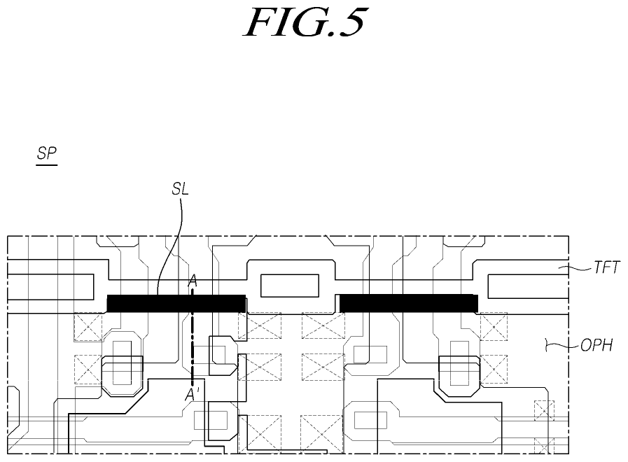

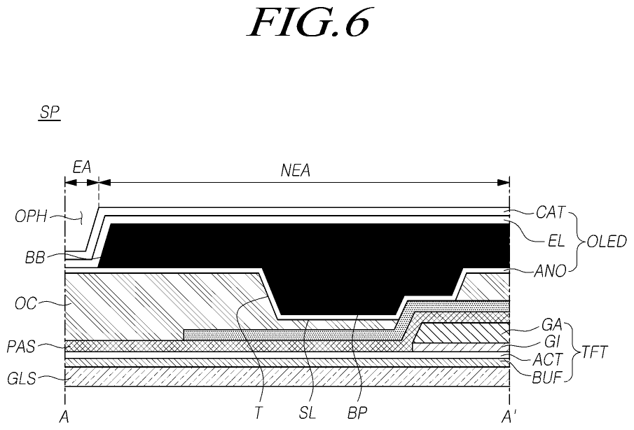

FIG. 5 is a plan view illustrating a portion of a subpixel according to an embodiment, and FIG. 6 is a cross-sectional view taken along line A-A′ of FIG. 5.

The display device 100 can be divided into a top emission type and a bottom emission type according to the direction in which the light emitted from the light emitting element is transmitted. Hereinafter, embodiments in which the display device is of the bottom emission type are described.

Referring to FIGS. 5 and 6, the display device 100 can include a substrate GLS, a thin film transistor TFT, a passivation layer PAS, a light emitting element OLED, an overcoat layer OC, and a black bank layer BB.

The substrate GLS can include an emission area EA and a non-emission area NEA. Here, the emission area EA can be an area in which an opening OPH of a black bank layer BB, which is described below, is positioned, and the non-emission area NEA can be defined as an area in which the black bank layer BB is positioned.

The substrate GLS can include a red R-subpixel R-SP, a green G-subpixel G-SP, a blue B-subpixel B-SP, and a white W-subpixel W-SP adjacent to each other. Accordingly, a full color can be implemented by emitting red light R, green light G, blue light B, and white light W.

The thin film transistor TFT can be disposed on the substrate GLS and can include a driving thin film transistor DT for switching driving power provided to the first electrode ANO, which is described below, and/or a switching thin film transistor SW for providing a data signal to the driving thin film transistor DT.

The thin film transistor TFT can be deteriorated by external light, thereby generating negative bias temperature illumination stress (NBTiS). In this case, since the threshold voltage of the thin film transistor TFT is changed and the reliability of the thin film transistor TFT can be deteriorated, it is preferable to dispose the thin film transistor TFT to be as far away as possible from the opening OPH through which external light is incident.

The thin film transistor TFT can include a buffer layer BUF, a semiconductor layer ACT, a gate electrode GA, and an insulation film GI.

The buffer layer BUF is for protecting the thin film transistor TFT from impurities such as alkali ions generated in the manufacturing process, and can be disposed on the substrate GLS. For example, the buffer layer BUF can be formed of silicon oxide (SiOx), silicon nitride (SiNx), or a combination thereof.

The semiconductor layer ACT can be disposed on the buffer layer BUF and can be formed of a transparent conductive material. For example, the semiconductor layer ACT can be formed of a transparent conductive material such as indium zinc oxide (IZO) or indium gallium zinc oxide (IGZO). As described above, when the semiconductor layer ACT is formed of a transparent conductive material, the semiconductor layer ACT can be disposed to overlap the opening OPH, thereby enhancing the aperture ratio.

Further, the semiconductor layer ACT can be formed of a silicon semiconductor or an oxide semiconductor. The silicon semiconductor can include amorphous silicon or crystallized polycrystalline silicon. Here, the polycrystalline silicon has high mobility (100 cm2/Vs or more), low energy consumption power, and excellent reliability, and thus can be applied to a gate driver and/or a multiplexer (MUX) for a driving element or to the driving thin film transistor DT in the pixel. Meanwhile, since the oxide semiconductor has a low off-current, the oxide semiconductor is suitable for the switching thin film transistor SW having a short on time and maintaining a long off time.

The gate electrode GA can be disposed where the emission area EA is positioned in the semiconductor layer ACT. The gate electrode GA can be formed of any one selected from the group consisting of molybdenum (Mo), aluminum (Al), chromium (Cr), gold (Au), titanium (Ti), nickel (Ni), neodymium (Nd), and copper (Cu), an alloy thereof, or a combination thereof. The gate electrode GA can include a source electrode and a drain electrode and can be electrically connected to the semiconductor layer ACT.

The gate insulation film GI can be disposed between the semiconductor layer ACT and the gate electrode GA to insulate between the semiconductor layer ACT and the gate electrode GA. For example, the gate insulation film GI can be formed of silicon oxide (SiOx), silicon nitride (SiNx), or a combination thereof.

The passivation layer PAS is an insulation film for protecting an element positioned below, and can cover an upper portion of the thin film transistor TFT. For example, the passivation layer PAS can be formed of silicon oxide layer SiOx, silicon nitride layer SiNx, or a combination thereof.

The light emitting element OLED can be electrically connected to the thin film transistor TFT. Specifically, the light emitting element OLED can include a first electrode ANO, a light emitting layer EL, and a second electrode CAT.

The first electrode ANO, as an anode electrode, can be interposed between the overcoat layer OC and the black bank layer BB, can be formed of a transparent conductive material, and can be disposed in the emission area EA and the non-emission area NEA. For example, the first electrode ANO can be formed of a transparent electrode material such as indium tin oxide (ITO), indium zinc oxide (IZO), or zinc oxide (ZnO).

The light emitting layer EL can be disposed on the first electrode ANO. For example, the light emitting layer EL, as an organic compound layer, can include a hole injection layer HIL, a hole transport layer HTL, an active layer EML, an electron transport layer ETL, and an electron injection layer EIL.

The second electrode CAT, as a cathode electrode, can be disposed on the light emitting layer EL. For example, the second electrode CAT can be formed of a transparent electrode material such as indium tin oxide (ITO), indium zinc oxide (IZO), or zinc oxide (ZnO).

The overcoat layer OC is a planarization layer for mitigating a step of the lower structure, and can be disposed on the passivation layer PAS. For example, the overcoat layer OC can be formed of an organic material such as polyimide, benzocyclobutene series resin, acrylate, or the like.

The overcoat layer OC can have a slit SL or a through hole (or through-hole) H recessed toward the passivation layer PAS. In this embodiment, for convenience of description, an example in which the slit SL is formed is described.

The slit SL can be formed in the non-emission area NEA. The position of the slit SL can vary depending on the structure of the thin film transistor TFT, which is described in detail below.

The black bank layer BB is for absorbing external light and can be disposed on the overcoat layer OC. For example, the black bank layer BB can be formed of one selected from a black resin, graphite powder, gravure ink, black spray, and black enamel, which are photosensitive organic insulating materials having low dielectric constant, or a combination thereof.

The black bank layer BB can be separated by the emission area to form an opening OPH. In other words, an emission area can be secured through the opening OPH. By the black bank layer BB, external light introduced from the upper portion can be absorbed.

However, external light incident through the opening OPH can be reflected from each layer and absorbed by the black bank layer BB, but can be directly introduced into the thin film transistor TFT to generate NBTiS.

To address this issue, the black bank layer BB can have a protrusion BP positioned in the slit SL in the lower surface. In other words, the protrusion BP can be formed in a shape corresponding to the slit SL and can be positioned in the slit SL. Due to this structure, the lower portion of the protrusion BP can contact the overcoat layer OC.

As described above, when the protrusion BP is provided in the black bank layer BB, external light introduced through the opening OPH can be absorbed by the protrusion BP.

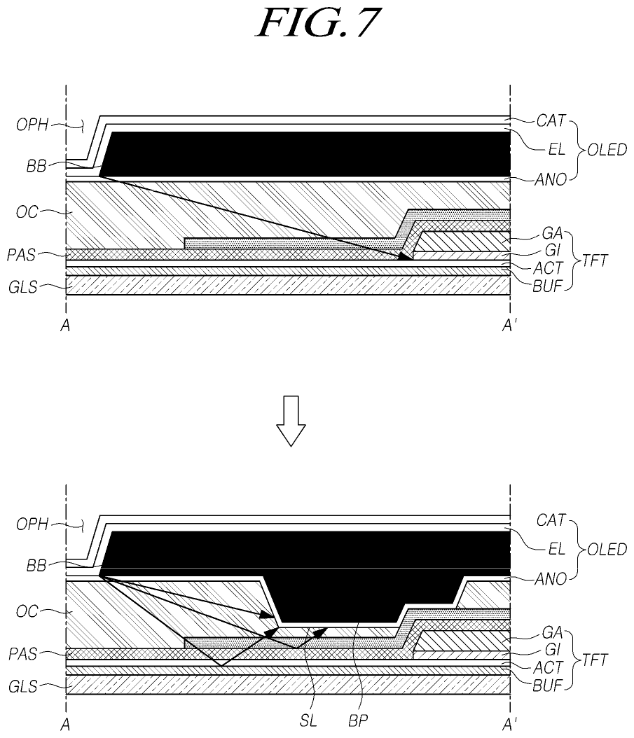

FIG. 7 is a view illustrating comparison in external light path between a black bank layer with no protrusion and a black bank layer with a protrusion. An example of absorbing external light incident on the emission area EA through the protrusion BP of the black bank layer BB is described with reference to FIG. 7.

As illustrated in FIG. 7, in the black bank layer BB without the protrusion BP, the external light transmitted without being reflected from the passivation layer PAS of the external light incident through the opening OPH is incident on the thin film transistor TFT, causing NBTiS.

However, since the slit SL is formed in the overcoat layer OC according to an embodiment of the disclosure, a protrusion BP which is inserted to the slit SL can be formed on a lower portion of the black bank layer BB. The protrusion BP can directly absorb external light incident through the opening OPH. Accordingly, since the amount of external light incident on the thin film transistor TFT can be remarkably reduced, NBTiS can be mitigated.

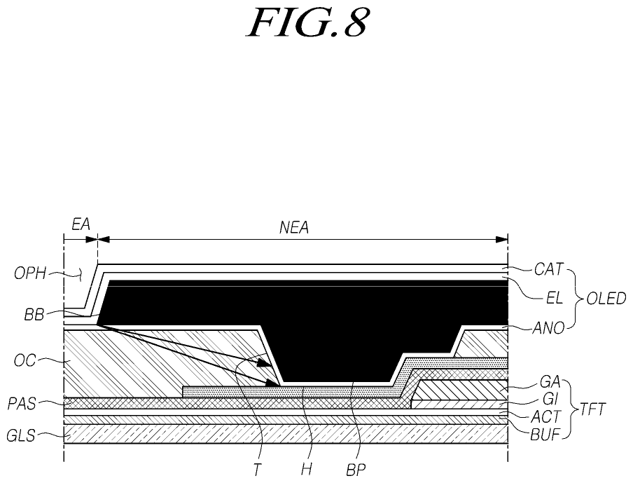

Meanwhile, a step T (e.g., FIG. 8) can be formed in the overcoat layer OC by the slit SL or the through hole H. The step T can be formed to be inclined downward from the non-emission area NEA to the emission area EA.

As described above, as the step T has an inclined surface formed to be inclined downward from the emission area EA to the non-emission area NEA, the protrusion BP positioned in the slit SL or the through hole H can also have an inclined surface corresponding thereto. Since the protrusion BP having such an inclined surface can absorb more external light than the protrusion BP having no inclined surface, NBTiS can be mitigated more efficiently.

FIG. 8 is a cross-sectional view illustrating a portion of a subpixel according to another embodiment of the disclosure. An example of absorbing external light incident on the light emitting area through the protrusion BP of the black bank layer BB is described with reference to FIG. 8.

Referring to FIG. 8, a through hole H can be formed in the overcoat layer OC according to an embodiment of the disclosure. In other words, a slit SL can be formed in the overcoat layer OC according to the embodiment of FIGS. 6 and 7, whereas a through hole H can be formed in the overcoat layer OC according to the embodiment of the disclosure.

As described above, when the through hole H is formed in the overcoat layer OC, the depth of the protrusion BP, i.e., the length in the vertical direction in the drawing can be longer than that of the slit SL, and thus more external light can be absorbed.

Meanwhile, when the through hole H is formed in the overcoat layer OC, NBTiS can be most efficiently mitigated because more external light can be absorbed than the slit SL structure, but the passivation layer PAS positioned below can be damaged during the process for forming the through hole H. Accordingly, it is preferable to minimize the distance between the protrusion BP and the passivation layer PAS by forming the slit SL to the maximum depth.

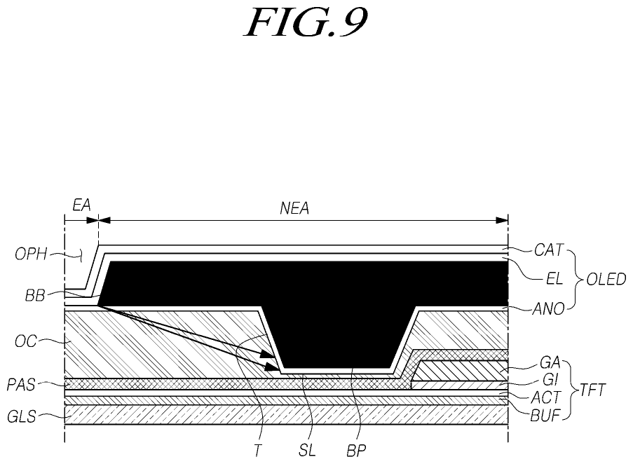

FIG. 9 illustrates a structure in which the depth of the slit SL is maximally formed, and for example, the distance between the protrusion BP and the passivation layer PAS can be 1 to 6000 Å.

Referring to FIG. 9, the distance between the protrusion BP and the passivation layer PAS can be formed by allowing the residual film of the overcoat layer OC positioned in the slit SL to have a thickness of 1 to 6000 Å. For example, the slit SL can be formed by etching a portion of the overcoat layer OC, and the residual film of the slit SL should be formed considering the initial thickness of the overcoat layer OC. In other words, as the thickness of the residual film of the slit SL decreases, it can be filled with more black bank layer BB to block more external light. When the overcoat layer OC is etched to form the slit SL, the residual film thickness of the slit SL considering the initial thickness value of the overcoat layer OC without damaging the passivation layer PAS positioned under the overcoat layer OC can be 1 to 6000 Å.

In other words, if the thickness of the residual film of the slit SL is less than 1 Å, the passivation layer PAS can be damaged when the overcoat layer OC is etched, and if the thickness of the residual film of the slit SL exceeds 6000 Å, the depth of the protrusion BP of the black bank layer BB filling the slit SL can be reduced, thereby reducing the blocking efficiency of external light. Accordingly, by forming the residual film thickness of the overcoat layer OC to 1 to 6000 Å, the distance between the protrusion BP and the passivation layer PAS can be 1 to 6000 Å.

As such, when the depth of the slit SL is maximized, the depth of the protrusion BP can be increased. In this case, since the protrusion BP can absorb light directly incident through the opening OPH, the structure of the color filter layer CF can be removed. The color filter layer CF can be optionally installed depending on the depth of the protrusion BP.

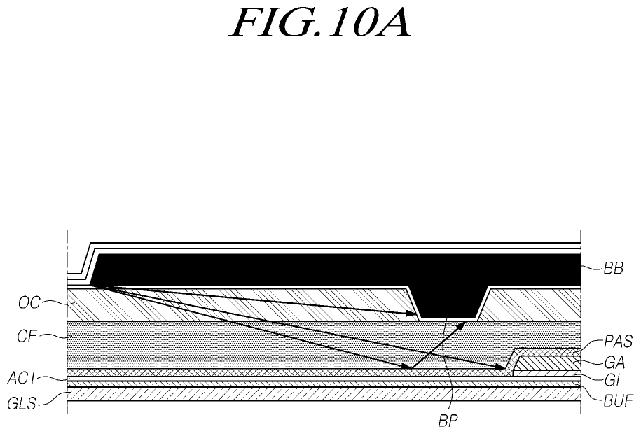

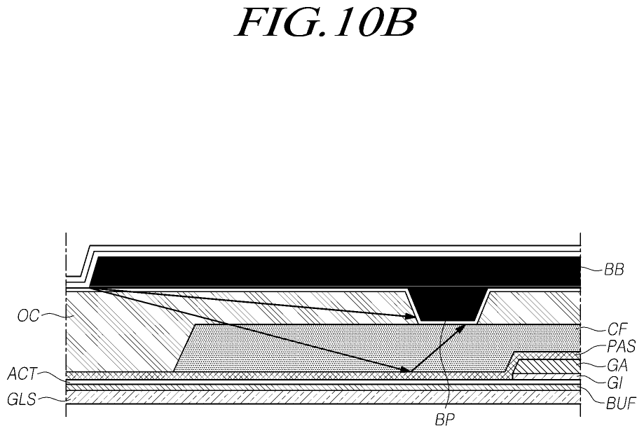

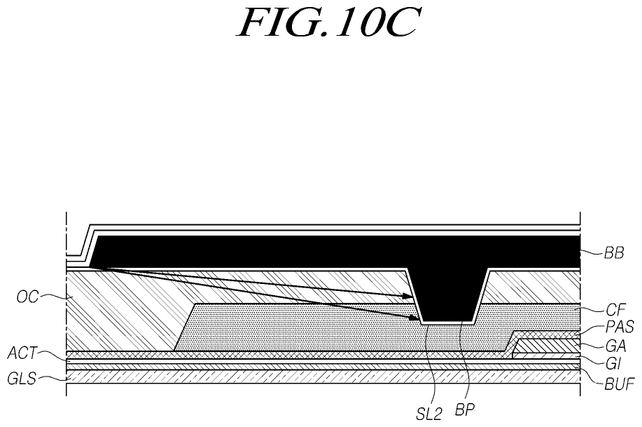

FIGS. 10A, 10B, and 10C are cross-sectional views illustrating embodiments of the present disclosure, which have a color filter layer in a display device.

Referring to FIGS. 10A to 10C, a color filter layer CF disposed between the passivation layer PAS and the overcoat layer OC of a display device can be further included.

As described above, when the color filter layer CF is further included between the passivation layer PAS and the overcoat layer OC, the color filter layer CF, together with the protrusion BP, can absorb external light incident on the opening OPH. In the color filter layer CF, since it is difficult to absorb the white light W, the color filter layer CF can be provided on the passivation layer PAS only when the subpixel SP is formed with the R-subpixel R-SP, the G-subpixel G-SP, and the B-subpixel B-SP.

The color filter layer CF can be disposed in both the emission area EA and the non-emission area NEA as illustrated in FIG. 10A, or can be disposed only in the non-emission area NEA as illustrated in FIG. 10B. For example, in the R-subpixel R-SP, the G-subpixel G-SP, and the B-subpixel B-SP, the color filter layer CF can be disposed in the emission area EA and the non-emission area NEA to be connected to the thin film transistor TFT, and in the W-subpixel B-SP, the color filter layer CF can be disposed only in the non-emission area NEA or selectively may not be provided.

Referring to FIG. 10C, a slit SL2 or a through hole can be formed in an upper portion of the color filter layer CF, and a protrusion BP can be positioned in the slit SL2 or the through hole of the color filter layer CF through the overcoat layer OC. This is because the white light W is difficult to absorb in the color filter layer CF, and thus the light absorption rate can be lower than that of the protrusion BP. In other words, the area of the protrusion BP can be further secured through the slit SL2 or the through hole formed in the color filter layer CF, thereby enhancing the light absorption rate.

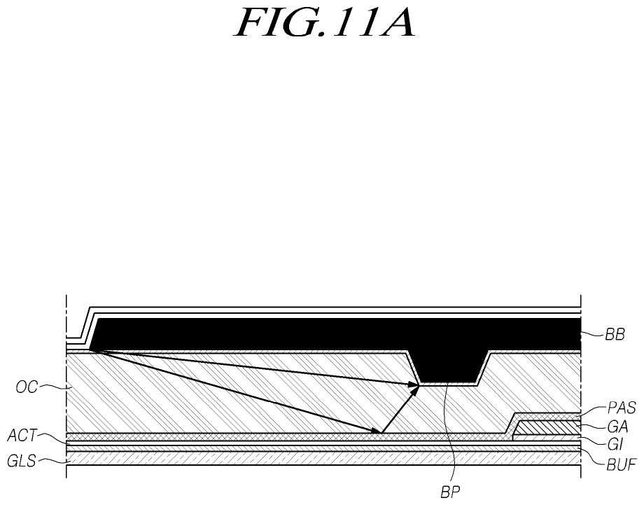

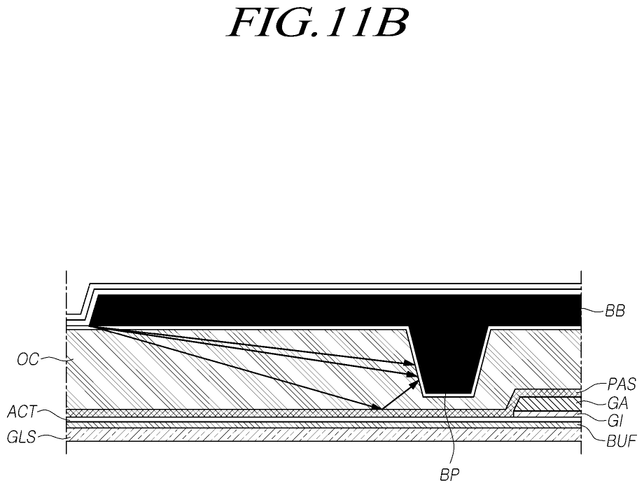

FIGS. 11A and 11B are cross-sectional views illustrating embodiments of the present disclosure, with no color filter layer.

Referring to FIGS. 11A and 11B, the length and depth of the protrusion BP can be formed to differ as necessary. For example, the length of the protrusion BP can be 1 to 10 μm. This is because it is difficult to form the protrusion BP when the length of the protrusion BP is less than 1 μm, and it can be difficult to secure the aperture ratio when the length of the protrusion BP exceeds 10 μm.

As illustrated in FIG. 11B, when the depth of the protrusion BP is formed to be greater, more external light can be absorbed. Therefore, when the color filter layer CF is not provided, it is preferable to form the depth of the protrusion BP to be as large as possible.

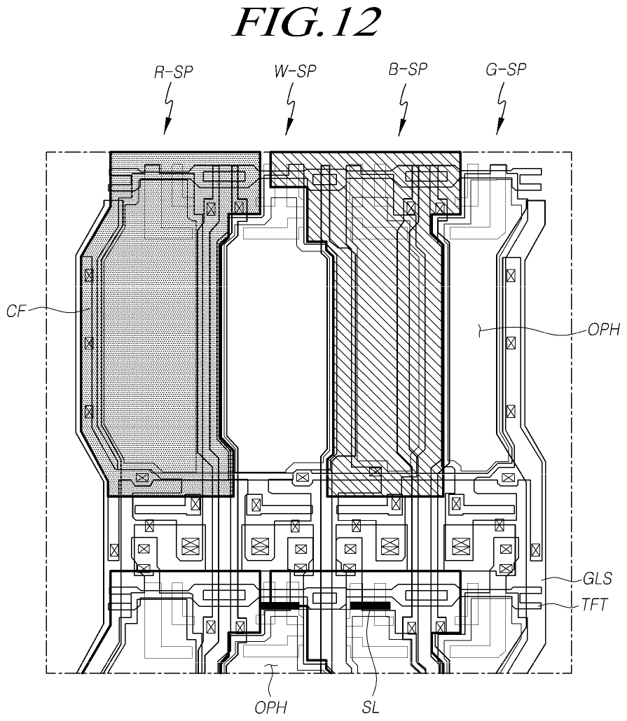

FIGS. 12 to 16 are plan views illustrating a structure in which a slit/through hole positioned in a pixel area is disposed according to an embodiment of the disclosure. The disposition structure of the slit SL/through hole H described above can be configured by applying the embodiments illustrated in FIGS. 12 to 16. Hereinafter, for convenience of description, it is described that the slit SL is formed in FIGS. 12 to 16.

Referring to FIG. 12, a red R-subpixel R-SP, a white W-subpixel W-SP, a blue B-subpixel B-SP, and a green G-subpixel G-SP adjacent to each other can be disposed on the substrate GLS from left to right in the drawing. The slit SL can be disposed between the opening OPH and the thin film transistor TFT on the substrate GLS. This is to effectively prevent external light introduced from the opening OPH through the protrusion BP positioned in the slit SL from entering the thin film transistor TFT. In this case, the slit SL can be recessed in the overcoat layer OC to form the residual film thickness of the overcoat layer OC to 1 to 6000 Å.

Meanwhile, the slit SL can be formed only in the B-subpixel B-SP and the W-subpixel W-SP, and the R-subpixel R-SP and the G-subpixel G-SP can block external light through stacking of the color filter layer CF. This is because the difference in the absorption rate of external light by wavelength of the color filter layer CF is different. When the slit SL is formed in the B-subpixel B-SP and the W-subpixel W-SP, the color filter layer CF around the thin film transistor TFT can be excluded, and thus the aperture ratio can be enhanced.

In the present embodiment, although the slit SL is positioned between the opening OPH and the thin film transistor TFT, the slit SL can be disposed between the opening OPH and the thin film transistor TFT, and a portion thereof can overlap the thin film transistor TFT. In this case, since the area of the slit SL can be formed to be larger, external light introduced through the opening OPH can be more effectively blocked.

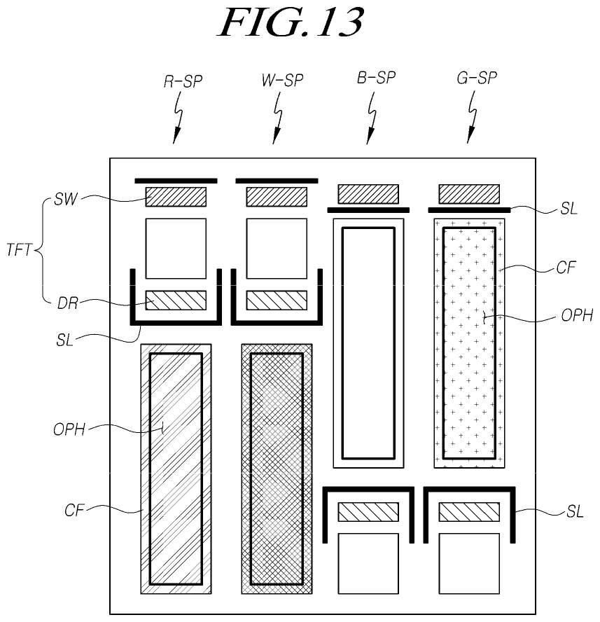

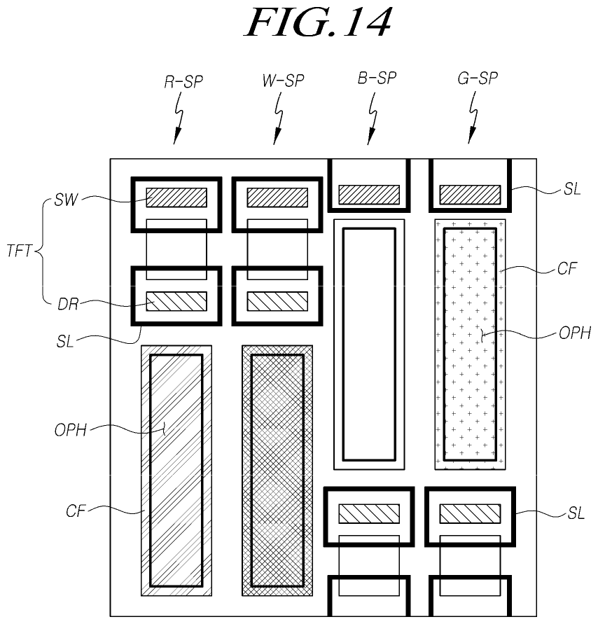

Meanwhile, as illustrated in FIGS. 13 and 14, the slit SL can be formed to surround the outer periphery of the thin film transistor TFT close to the opening OPH.

Referring to FIG. 13, the slit SL can be provided in a combination of a “⊏” shape and a “-” shape and can be formed to surround the outer periphery of the thin film transistor TFT between the opening OPH and the thin film transistor TFT. For example, a slit SL having a “-” shape can be positioned on one side of the switching thin film transistor SW, and a slit SL having a “⊏” shape can be positioned on one side of the driving thin film transistor DT. In this case, since the slit SL can be formed according to the structures of the switching thin film transistor SW and the driving thin film transistor DT, external light can be more efficiently blocked.

In the present embodiment, it is illustrated that the slit SL is formed in all of the R-subpixel R-SP, the W-subpixel W-SP, the B-subpixel B-SP, and the G-subpixel G-SP. However, the slit SL can be formed only in the B-subpixel B-SP and the W-subpixel W-SP.

Referring to FIG. 14, the slit SL can be formed in a “□” shape to surround the outer periphery of the thin film transistor TFT. In this case, the slit SL can be positioned between the opening OPH and the thin film transistor TFT or can overlap an upper portion of the thin film transistor TFT close to the opening OPH.

In the present embodiment, it is illustrated that the slit SL is formed in all of the R-subpixel R-SP, the W-subpixel W-SP, the B-subpixel B-SP, and the G-subpixel G-SP. However, the slit SL can be formed only in the B-subpixel B-SP and the W-subpixel W-SP.

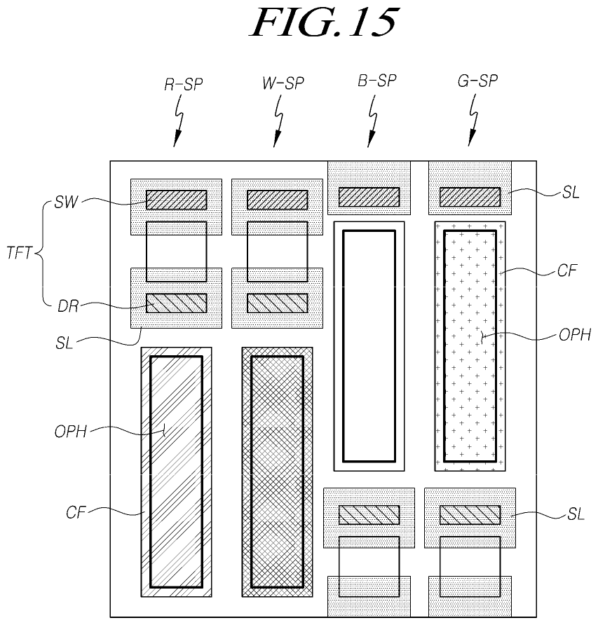

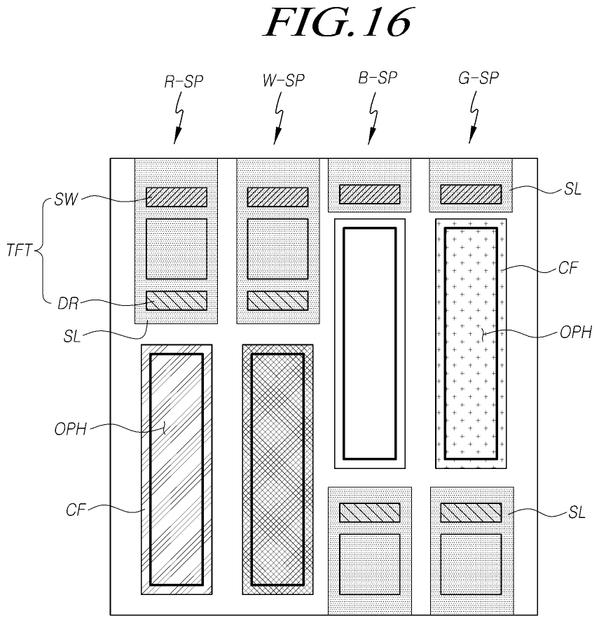

As illustrated in FIGS. 15 and 16, the slit SL can be formed to overlap an upper portion of the thin film transistor TFT close to the opening OPH. In this case, the slit SL can be recessed in the overcoat layer OC to form the residual film thickness of the overcoat layer OC to 1 to 6000 Å. In the following embodiment, the structure recessed in the overcoat layer OC has been described as the slit SL, but can also be formed as the through hole H.

Referring to FIG. 15, the slit SL can be formed in a rectangular shape having a preset area, and a pair of slits SL can be provided to overlap the upper portions of the switching thin film transistor SW and the driving thin film transistor DR, respectively.

In the present embodiment, it is illustrated that the slit SL is formed in all of the R-subpixel R-SP, the W-subpixel W-SP, the B-subpixel B-SP, and the G-subpixel G-SP. However, the slit SL can be formed only in the B-subpixel B-SP and the W-subpixel W-SP. The color filter layer CF can be optionally provided in the inner area of the slit SL.

Referring to FIG. 16, the slit SL can be formed in a plate shape having a preset area and can overlap the switching thin film transistor SW and the driving thin film transistor DT.

In the present embodiment, it is illustrated that the slit SL is formed in all of the R-subpixel R-SP, the W-subpixel W-SP, the B-subpixel B-SP, and the G-subpixel G-SP. However, the slit SL can be formed only in the B-subpixel B-SP and the W-subpixel W-SP. The color filter layer CF can be optionally provided in the inner area of the slit SL.

Embodiments of the disclosure described above are briefly described below.

Embodiments of the disclosure can provide a display device comprising a substrate including an emission area and a non-emission area, a thin film transistor disposed on the substrate, a passivation layer covering an upper portion of the thin film transistor, an overcoat layer disposed on the passivation layer and having a slit or through hole recessed toward the passivation layer, and a black bank layer disposed on the overcoat layer and formed to have a shape corresponding to the slit or through hole to form a protrusion positioned in the slit or through hole.

According to embodiments of the disclosure, external light incident on the emission area can be absorbed by the protrusion of the black bank layer.

According to embodiments of the disclosure, the black bank layer can be separated at the emission area, as a boundary, to form an opening.

According to embodiments of the disclosure, the slit or through hole can be disposed between the opening and the thin film transistor.

According to embodiments of the disclosure, the slit or through hole can be disposed between the opening and the thin film transistor and has a portion overlapping the thin film transistor.

According to embodiments of the disclosure, the slit or through hole can be formed to have a structure surrounding the thin film transistor adjacent to the opening.

According to embodiments of the disclosure, the slit or through hole can overlap an upper portion of the thin film transistor adjacent to the opening.

According to embodiments of the disclosure, the slit or through hole can be formed in the non-emission area.

According to embodiments of the disclosure, the overcoat layer can have a step formed by the slit or through hole. The step can be formed to be inclined downward from the emission area to the non-emission area.

According to embodiments of the disclosure, a length of the protrusion can be 1 μm to 10 μm.

According to embodiments of the disclosure, a distance between the protrusion and the passivation layer can be 1 Å to 6000 Å.

According to embodiments of the disclosure, the display device can further comprise a color filter layer disposed between the passivation layer and the overcoat layer.

According to embodiments of the disclosure, a slit or through hole can be formed in an upper portion of the color filter layer, and the protrusion can be positioned in the slit or through hole of the color filter layer through the overcoat layer.

According to embodiments of the disclosure, the substrate can include a red R-subpixel, a green G-subpixel, a blue B-subpixel, and a white W-subpixel adjacent to each other. The color filter layer can be provided on the passivation layer when the subpixel is formed as the R-subpixel, the G-subpixel, and the B-subpixel.

According to embodiments of the disclosure, the substrate can include a red R-subpixel, a green G-subpixel, a blue B-subpixel, and a white W-subpixel adjacent to each other. The slit or through hole can be formed in the B-subpixel and the W-subpixel.

According to embodiments of the disclosure, the thin film transistor can include a driving thin film transistor and/or a switching thin film transistor.

According to embodiments of the disclosure, the thin film transistor can include a buffer layer disposed on the substrate, a semiconductor layer disposed on the buffer layer and formed of a transparent conductive material, a gate electrode disposed in a portion of the semiconductor layer where the emission area is positioned, and a gate insulation film disposed between the semiconductor layer and the gate electrode.

According to embodiments of the disclosure, the display device can further comprise a light emitting element electrically connected to the thin film transistor. The light emitting element can include a first electrode interposed between the overcoat layer and the black bank layer, formed of a transparent conductive material, and disposed in the emission area and the non-emission area, a light emitting layer disposed on the first electrode, and a second electrode disposed on the light emitting layer.

According to embodiments of the disclosure, there can be provided a display device capable of enhancing the NBTiS characteristics and the reliability of the thin film transistor by minimizing the amount of light introduced to the thin film transistor by absorbing the light incident on the opening through the black bank layer.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein can be applied to other embodiments and applications without departing from the spirit and scope of the disclosure. The above description and the accompanying drawings provide an example of the technical idea of the disclosure for illustrative purposes only. For example, the disclosed embodiments are intended to illustrate the scope of the technical idea of the disclosure.

What is claimed is:

1. A display device, comprising:
a substrate including an emission area and a non-emission area;
a thin film transistor disposed on the substrate;
a passivation layer covering an upper portion of the thin film transistor;
an overcoat layer disposed on the passivation layer and having a slit or through hole recessed toward the passivation layer; and
a black bank layer disposed on the overcoat layer and having a shape corresponding to the slit or through hole of the overcoat layer, so as to form a protrusion positioned in the slit or through hole.

2. The display device of claim 1, wherein external light incident on the emission area is absorbed by the protrusion of the black bank layer.

3. The display device of claim 1, wherein the black bank layer is separated at the emission area, as a boundary, to form an opening.

4. The display device of claim 3, wherein the slit or through hole of the overcoat layer is disposed between the opening and the thin film transistor.

5. The display device of claim 3, wherein the slit or through hole of the overcoat layer is disposed between the opening and the thin film transistor, and has a portion overlapping the thin film transistor.

6. The display device of claim 3, wherein the slit or through hole of the overcoat layer is formed to have a structure surrounding the thin film transistor adjacent to the opening.

7. The display device of claim 3, wherein the slit or through hole of the overcoat layer overlaps an upper portion of the thin film transistor adjacent to the opening.

8. The display device of claim 1, wherein the slit or through hole of the overcoat layer is formed in the non-emission area.

9. The display device of claim 1, wherein the overcoat layer has a step formed by the slit or through hole, and
wherein the step is formed to be inclined downwardly from the emission area to the non-emission area.

10. The display device of claim 1, wherein a length of the protrusion of the black bank layer is about 1 μm to 10 μm.

11. The display device of claim 1, wherein a distance between the protrusion of the black bank layer and the passivation layer is about 1 Å to 6000 Å.

12. The display device of claim 1, further comprising a color filter layer disposed between the passivation layer and the overcoat layer.

13. The display device of claim 12, wherein the color filter layer includes a slit or through hole formed in an upper portion of the color filter layer, and
wherein the protrusion is positioned in the slit or through hole of the color filter layer through the overcoat layer.

14. The display device of claim 12, wherein the substrate includes a red subpixel, a green subpixel, a blue subpixel, and a white subpixel adjacent to each other, and
wherein the color filter layer is provided on the passivation layer when the subpixel is formed as the red subpixel, the green subpixel, or the blue subpixel.

15. The display device of claim 1, wherein the substrate includes a red subpixel, a green subpixel, a blue subpixel, and a white subpixel adjacent to each other, and
wherein the slit or through hole of the overcoat layer is formed in the blue subpixel and the white subpixel.

16. The display device of claim 1, wherein the thin film transistor includes at least one of a driving thin film transistor and a switching thin film transistor.

17. The display device of claim 1, wherein the thin film transistor includes:
a buffer layer disposed on the substrate;
a semiconductor layer disposed on the buffer layer and including a transparent conductive material;
a gate electrode disposed in a portion of the semiconductor layer where the emission area is positioned; and
a gate insulation film disposed between the semiconductor layer and the gate electrode.

18. The display device of claim 1, further comprising a light emitting element electrically connected to the thin film transistor,
wherein the light emitting element includes:
a first electrode interposed between the overcoat layer and the black bank layer, including a transparent conductive material, and disposed in the emission area and the non-emission area;
a light emitting layer disposed on the first electrode; and
a second electrode disposed on the light emitting layer.
